(19) United States
(12) Patent Application Publication
(10) Pub. No.: US 2020/0166548 A1
(43) Pub. Date: May 28, 2020

(54) MAGNETIC CORE FOR A CURRENT MEASUREMENT SENSOR

(71) Applicant: Valeo Siemens eAutomotive France SAS, Cergy (FR)

(72) Inventor: Abdelfatah Kolli, Bobigny (FR)

(21) Appl. No.: 16/689,619

(22) Filed: Nov. 20, 2019

(30) Foreign Application Priority Data
Nov. 22, 2018 (FR) 1871700

(51) Int. Cl. G01R 15/18; H01F 17/04

(52) U.S. Cl. CPC G01R 15/183; H01F 17/04

(57) ABSTRACT

The subject matter of the invention is a magnetic core for a current measurement sensor, said magnetic core comprising at least one ferromagnetic part, comprising at least one concave portion, extending along a longitudinal plane and delimiting at least one air gap, said air gap being capable of receiving a sensitive element of a measurement sensor, and an inner space, capable of receiving the strip of an electrical conductor. The magnetic core has a longitudinal section of elliptical shape.

### CROSS-REFERENCE TO RELATED APPLICATION

This application claims foreign priority benefits under 35 U.S.C. § 119 to French Patent Application No. 1871700 filed on Nov. 22, 2018, the content of which is hereby incorporated by reference in its entirety.

### TECHNICAL FIELD

The present invention relates to a magnetic core for a current measurement sensor and more specifically a magnetic core mounted in an electrical equipment of an automobile vehicle, notably electric or hybrid, in order to concentrate the magnetic field at the level of the sensitive element of a current measurement sensor in said electrical equipment. The invention notably aims to improve the performances of such a magnetic core.

### BACKGROUND

As is known, an electric or hybrid automobile vehicle includes an electric motorisation system supplied by a high voltage power supply battery via an on board high voltage electrical network and a plurality of auxiliary items of electrical equipment supplied by a low voltage power supply battery via an on board low voltage electrical network.

The high voltage power supply battery ensures an energy supply function for the electric motorisation system enabling the propulsion of the vehicle. More precisely, in order to command the electrical machine driving the wheels of the vehicle or to store the energy supplied by the electrical machine in the high voltage power supply battery, it is known to use an inverter making it possible to convert the direct current supplied by the high voltage power supply battery into one or more alternating command currents, for example sinusoidal, or to convert one or more alternating command currents supplied by the electrical machine into a direct current of which the electrical energy may then be stored by the high voltage power supply battery.

In a known solution, the inverter is in the form of a box in which are mounted electronic power components through which passes the energy supplying the electrical machine or the energy received from the electrical machine. These electronic power components are controlled by a driver, which is itself controlled by an electronic control unit. In the case of a three-phase motor, the inverter includes three electrical conductors, called “phase conductors”, making it possible to command the motor using three so-called “phase” currents phase shifted two by two, for example by 120°. These phase currents are generated by the inverter from the current delivered by the high voltage battery. To do so, the inverter includes a first battery conductor, called “positive conductor”, suited to being connected to a positive potential of the battery, and a second battery conductor, called “negative conductor”, suited to being connected to a negative potential of the high voltage power supply battery.

The electronic control unit commands the driver in order that it controls the electronic power components so that they carry out the conversion of the direct current into alternating phase currents or vice-versa. To this end, the electronic control unit is in the form of an electronic card on which are mounted electronic components connected by electrical tracks and making it possible to command the driver. Similarly, the driver is in the form of an electronic card on which are mounted electronic components connected by electrical tracks and making it possible to command the electronic components.

In order to control the operation of the inverter, it may be necessary to detect variations in the intensity of the phase currents circulating in each phase conductor. To this end, it is known to use for each phase conductor a sensor, called “Hall effect sensor”, connected to the electronic control unit and comprising a magnetically sensitive element extending near to the phase conductor. Thus, when a current circulates in the phase conductor, it transmits a magnetic field which the sensitive element of the sensor measures in order to deduce therefrom the value of the intensity of said current or the variations in intensity of said current.

In order to improve the precision of the measurement, it is known to channel the magnetic field generated by the circulation of the current in the phase conductor using a magnetic core.

In existing solutions, such a magnetic core is constituted of a U- or C-shaped ferromagnetic part delimiting an air gap into which is inserted the sensitive element of the measurement sensor. Yet, such magnetic cores have a significant inner volume which leads to a narrow linearity range such that the measurements rapidly saturate when the current varies in a significant manner. Moreover, saturation leads to coupling effects (also called cross talk) on the magnetic cores of neighbouring sensors thereby deteriorating the quality of the measurements, which represent important drawbacks.

In order to offset in part these problems, a known solution consists in using a magnetic core of rectangular section with rounded corners (see FIG. 1) constituted of laminated ferromagnetic strips of low thickness, each of the order of 0.2 mm, and having a small inner volume in such a way as to surround as closely as possible the phase conductor. Such a magnetic core has a significant linearity range and limited coupling with the cores of neighbouring sensors.

Typically, a magnetic core may be characterised by its reluctance as follows:

$$= \frac{{L}_{C}}{{μ}_{0} {μ}_{r} S} \qquad [ Math . 1 ]$$

where

$$\begin{matrix} \text{?} & [ Math . 2 ] \\ \text{?} \text{indicates text missing or illegible when filed} & \end{matrix}$$

[symbol]

_{C} is the reluctance of the magnetic core, μ0 is the permeability of a vacuum, pr is the relative permeability of the ferromagnetic of the core, L_{C} is the average effective length of the magnetic field in the core. This average length is defined as the path situated at equidistance between the inner and outer edges of the core. S is the transversal section of the magnetic core, which corresponds notably to the section orthogonal to the magnetic flux traversing the magnetic core.

However, this core does not have a sufficient linearity range and/or a size for applications such as in an electrical equipment for a vehicle, for example an on board inverter or DC-DC converter or charger.

There thus exists a need for a magnetic core solution having an improved linearity range and/or size.

### SUMMARY

To this end, the subject matter of the invention is firstly a magnetic core for a current measurement sensor, said magnetic core comprising at least one concave portion, extending along a longitudinal plane and delimiting at least in part an air gap, said air gap being capable of receiving a sensitive element of a measurement sensor, and the concave portion delimiting an inner space, capable of receiving an electrical conductor, said magnetic core being remarkable in that it has a longitudinal section of elliptical shape.

The terms “longitudinal section of elliptical shape” are taken to mean that the longitudinal section of the device, when the metal part(s) are positioned to be used with a current measurement sensor, is of elliptical shape at least on its inner section.

The use of a longitudinal section of elliptical shape makes it possible to reduce the average effective length of the magnetic core compared to the prior art, which makes it possible to reduce the reluctance of the device compared to the prior art. The magnetic core thereby has a lower reluctance and thus a greater linearity range compared to the prior art at identical material and section. Alternatively, the magnetic core has a more restricted inner space (or volume) compared to the prior art at identical reluctance and identical linearity range. The use of a longitudinal section of elliptical shape thereby also makes it possible to adjust the inner space delimited by the concave portion(s) of the ferromagnetic part(s) in order to surround as closely as possible the strip of the electrical conductor.

In an embodiment, the magnetic core includes a single ferromagnetic part delimiting a single air gap, making the magnetic core monobloc, which notably makes it possible to obtain a high precision of the measurements made by the sensor.

In another embodiment, the magnetic core includes two opposite ferromagnetic parts delimiting two air gaps, which notably enables the measurement sensor to work on a linearity interval of important width.

Preferably, the average effective length of the magnetic core is less than 50 mm in order to reduce the reluctance thereof.

Further preferably, the reluctance of the magnetic core is less than 80000 Sturgeon (Henry⁻¹), for example 79577 Sturgeon in the case of an iron-silicon material of relative permeability μᵣ=20000.

Preferably, the ferromagnetic material constituting the at least one part is a ferroalloy, preferably an alloy of iron and silicon (ferrosilicon or iron silicide). The alloy of iron and silicon is a material of high saturation induction (going up to 2 T), which makes it possible to maintain an increased linearity range. Another advantage of such an alloy is its low cost.

In an embodiment, the ferroalloy is laminated in order to reduce the hysteresis of the material and consequently the losses in the material while improving the precision of the current measurement.

Advantageously, the width of the air gap is comprised between 3 and 8 mm, preferably between 3.5 and 5 mm. This makes it possible to reduce magnetic flux leakages, and consequently cross-talk (coupling effects) with surrounding elements.

Further advantageously, the thickness of the part is comprised between 3 and 12 mm, preferably of the order of 5 mm. Such a thickness may be a good compromise between the inner space of the magnetic core and the current range to measure (linearity).

The invention also relates to an electrical connection assembly, comprising at least one electrical conductor, notably at least in part in the form of a strip, and at least one magnetic core such as described previously, in which the electrical conductor extends through the magnetic core such that the magnetic core channels into its at least one air gap the magnetic fields generated by a current circulating in the electrical conductor.

In an embodiment, the electrical connection assembly includes a plurality of electrical conductors and a plurality of magnetic cores, each electrical conductor extending into the inner space of a respective magnetic core.

Advantageously, the electrical connection assembly includes an overmoulding holding together the magnetic cores.

Preferably, the inner edge of the magnetic core has a longitudinal section of ellipse shape, said ellipse being the smallest ellipse confined to the overall size of the conductor (in particular the portion of the electrical conductor comprised in the inner space) with a minimum distance d3 between the overall size of the electrical conductor and said inner edge. The inner edge corresponds to the part of the ellipse that defines the inner space of the magnetic core. The overall size corresponds to the external dimensions of the electrical conductor in the inner space defined by the magnetic core. The minimum distance d3 may be positive or zero.

In an embodiment, the electrical conductor has a parallelepiped section and is centred on the centre of the ellipse and in which the half major axis a and the half minor axis b of the ellipse are such that

$$a \geq \frac{f 1}{2} + d 1 , \qquad [ Math . 3 ]$$

where f1 is the width of the electrical conductor along the direction of the major axis a, d1 is a first margin between the periphery of the electrical conductor and the inner edge of the magnetic core along the major axis a. The minor axis b is such that the minimum distance between the periphery of the electrical conductor and the inner edge of the magnetic core, along a direction parallel to the minor axis b, is greater than or equal to d2, d2 being a second margin between the periphery of the electrical conductor and the inner edge of the magnetic core.

Preferably, one has:

$$a = \frac{f 1}{2} + d 1 \qquad [ Math . 4 ]$$

and b is such that the minimum distance between the overall size and the inner edge of the magnetic core along a direction parallel to the minor axis b is equal to d2.

Further preferably, one has: 1 mm<d1<5 mm and/or 0.5 mm<d2<5 mm and/or 0.5 mm<d3<5 mm. The distance d3 and the distances d1 and d2 make it possible to ensure an electrical isolation between the electrical conductor and the magnetic core.

The invention also relates to a sensor assembly comprising an electrical connection assembly such as described previously and a measurement sensor comprising a sensitive element extending into the at least one air gap of the at least one magnetic core, said sensitive element being configured in such a way as to measure an intensity of the magnetic field induced by a current circulating in the at least one corresponding electrical conductor.

Advantageously, the sensor assembly further includes an electronic card comprising an electrical connection circuit, the measurement sensor being electrically connected to said electrical connection circuit. Such an electronic card may for example be a driver of an electronic power module or electronic power components or instead an electronic control unit of an electrical equipment, such as an inverter or a voltage converter.

The invention also relates to an electrical equipment, notably for an automobile vehicle, comprising an electrical connection assembly such as described above.

Such an electrical equipment may for example be an inverter or a voltage converter.

The invention also relates to an electric or hybrid vehicle comprising an electrical machine, for example a motorisation machine, supplied by a high voltage power supply battery via an on board high voltage electrical network and an electrical equipment, for example an inverter, such as described previously, connected to said electrical machine.

### BRIEF DESCRIPTION OF THE DRAWINGS

The invention will be better understood on reading the description that follows, given uniquely by way of example, and by referring to the appended drawings given as non-limiting examples, in which identical references are given to similar objects and in which:

FIG. 1 shows the prior art,

FIG. 2 is a partial perspective view of a first embodiment of an assembly according to the invention,

FIG. 3 is a perspective view of a first embodiment of the magnetic core according to the invention,

FIG. 4 is a side view of the magnetic core of FIG. 3,

FIG. 5 is a close up view of one of the magnetic cores of the assembly of FIG. 2,

FIG. 6 is a side view of an alternative of the magnetic core of FIGS. 3 and 4,

FIG. 7 is a perspective view of the magnetic core of FIG. 6,

FIG. 8 is a partial perspective view of a second embodiment of the assembly according to the invention,

FIG. 9 is a perspective view of a second embodiment of the magnetic core according to the invention,

FIG. 10 is a side view of the magnetic core of FIG. 9,

FIG. 11 is a close up view of one of the magnetic cores of the assembly of FIG. 8,

FIG. 12 schematically illustrates an example of electrical connection assembly according to the invention in which the electrical conductor is a strip of rectangular section,

FIG. 13 schematically illustrates an example of electrical connection assembly according to the invention in which the electrical conductor has a section of irregular shape,

FIG. 14 is a perspective view of an overmoulding formed around the magnetic cores of the assembly of FIG. 2,

FIG. 15 is a perspective view of an overmoulding formed around magnetic cores mounted around electrical conductors each constituted of a flat metal strip.

It should be noted that the figures set out the invention in a detailed manner for implementing the invention, said figures obviously being able to serve to better define the invention if needs be.

### DETAILED DESCRIPTION

In the description that will be made hereafter, the invention will be described in its application to an electric or hybrid automobile vehicle without this limiting the scope of the present invention. In the example described hereafter, the vehicle notably includes an electrical machine, an electrical equipment, a high voltage power supply battery, an on board high voltage electrical network, a low voltage power supply battery, an on board low voltage electrical network and a plurality of auxiliary items of equipment. In this example, the electrical equipment is an inverter, without however this limiting the scope of the present invention. It will thus be noted that the electrical equipment could be for example a charger or direct current-direct current (DC-DC) converter on board the vehicle. The on board low voltage electrical network connects the low voltage power supply battery and the plurality of auxiliary items of equipment in order that the low voltage power supply battery supplies said auxiliary items of equipment. These auxiliary elements are electrical or electronic elements such as, for example, on-board computers, window winder motors, control systems, multimedia systems, etc. The low voltage power supply battery typically delivers for example a voltage of the order of 12 V, 24 V or 48 V. The recharging of the low voltage battery is carried out from the high voltage battery via a direct current into direct current voltage converter, commonly called DC-DC converter. The on board high voltage electrical network connects the high voltage power supply battery and the inverter in order that the high voltage power supply battery ensures a function of supplying the electrical machine with energy via the inverter. The high voltage power supply battery typically delivers a voltage comprised between 100 V and 900 V, preferably between 100 V and 500 V. The recharging of the high voltage power supply battery with electrical energy is carried out by connecting it, via the DC high voltage electrical network of the vehicle, to an external electrical network, for example the domestic AC electrical network. The electrical machine is a rotating electrical machine, preferably configured to drive the wheels of the vehicle from the energy supplied by the high voltage power supply battery.

More precisely, the electrical machine is an alternating current electrical machine supplied by a polyphase current source. For example, the electrical machine may be an alternating current motor. In the preferred example described hereafter, the electrical machine is supplied by a three-phase current source without this limiting the scope of the present invention. In this example, the command of the electrical machine is carried out by means of the inverter. The inverter makes it possible to convert the direct current supplied by the high voltage power supply battery into a plurality of alternating currents, for example sinusoidal, called “phase currents”, making it possible to command the electrical machine. Conversely, in another operating mode, the electrical machine can also supply alternating phase currents to the inverter in order that the inverter transforms them into a direct current making it possible to charge the high voltage power supply battery. In the example described hereafter, the inverter is configured to be connected to a three-phase electrical machine.

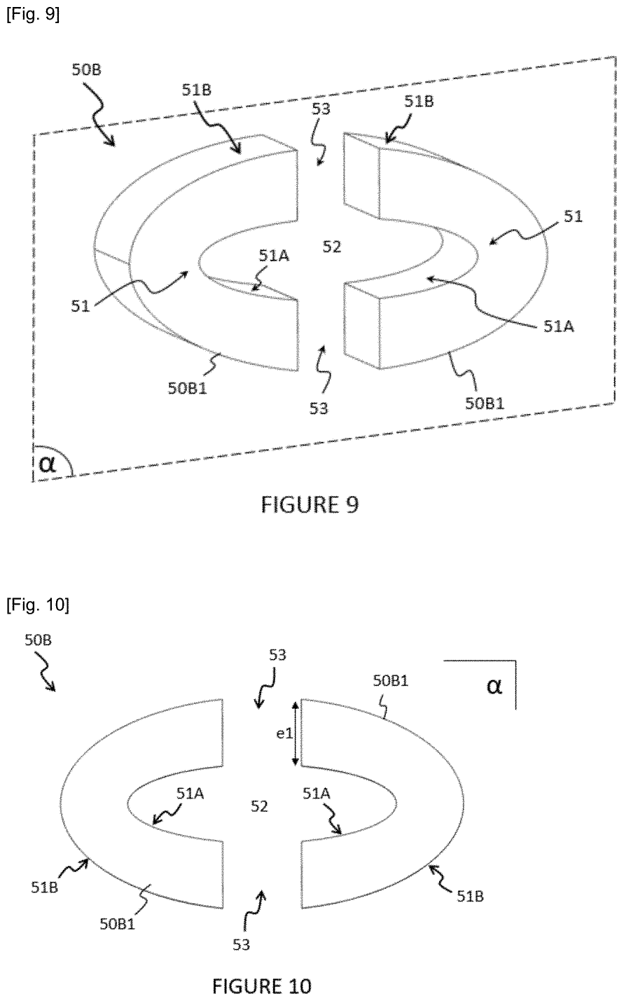

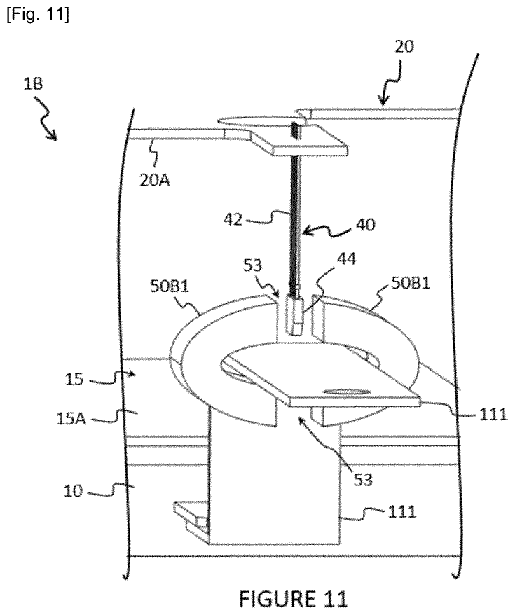

In FIGS. 2 to 7 is represented a first embodiment of an assembly 1A according to the invention and in FIGS. 8 to 11 a second embodiment of an assembly 1B according to the invention. These assemblies 1A, 1B, are notably each comprised in an inverter.

The inverter includes a box in which are mounted, with reference to FIGS. 2 and 8, an electronic power module 10 comprising electronic power components (not visible), a driver 15 and an electronic control unit 20 (not represented in FIG. 2 but present). The assembly, 1A, 1B further includes electrical phase conductors 111, 112, 113, making it possible to connect the inverter to the electrical machine.

The energy supplying the electrical machine or received from the electrical machine passes through the electronic power components of the electronic power module 10, in this example three in number, which are configured to transform the direct current into alternating currents or vice-versa. These electronic power components may include electronic switches, such as for example semiconductor transistors, arranged in electrical circuit to enable a commanded passage of electrical energy between the high voltage power supply battery and the electrical machine. In particular, the electronic power components may be bare semiconductor chips for which the body of the electronic power module 10 forms an encapsulation.

In the examples illustrated, the driver 15 is in the form of an electronic card 15A electrically connected to the electronic power components of the electronic power module 10. This electronic card comprises electronic components (not represented) connected together by conductive tracks notably making it possible to command the electronic power components, notably transistors or semiconductor chips. The electronic card 15A may notably comprise a first assembly of electrical tracks, called direct bus, and a second assembly of electrical tracks, called alternating bus, between which are connected the electronic power components. The alternating bus is connected to the electrical conductors 111, 112, 113 of the assembly 1A, 1B. In addition, the driver 15 may be configured to exchange data signals with the electronic control unit 20.

In the examples illustrated, the electronic control unit 20 is in the form of an electronic card 20A on which are mounted electronic components (not represented) connected together by conductive tracks and making it possible to command the driver 15.

In the examples illustrated, non-limiting, the electronic card 15A of the driver 15 and the electronic card 20A of the electronic control unit 20 are mounted in a superimposed manner. These electronic cards 15A, 20A may be fixed on a wall of the box 5 or on a support element (not represented, which may for example be a plate) suspended in the housing defined by the box 5.

Each electrical conductor 111, 112, 113 makes it possible to connect electrically an electronic power component of the electronic power module 10 to a phase of the electrical machine. To this end, each electrical conductor 111, 112, 113 traverses an opening of the box 5 to be able to connect the inverter 1, 1A, 1B to the electrical machine and notably to enable the circulation of alternating currents between the electronic power components of the electronic power module 10 and the electrical machine. Each electrical conductor 111, 112, 113 is in the form of a metal strip, for example made of copper, steel, aluminium or any other conductive material. This strip may optionally be folded back one or more times, as is the case in the example illustrated. Each electrical conductor 111, 112, 113 may further advantageously be covered with an anti-wear surface, for example composed of tin and nickel.

In order to measure the intensity of the current circulating in each electrical conductor 111, 112, 113, the assembly 1A, 1B includes, for each electrical conductor 111, 112, 113, a measurement sensor 40, i.e. three measurement sensors 40 in the examples illustrated. These measurement sensors 40 may be mounted, via one or more connection pins 42, on the electronic card of the driver 15 (as illustrated in FIG. 2) or instead the electronic card of the electronic control unit 20 (as illustrated in FIG. 8). Each measurement sensor 40 includes a sensitive element 44 arranged opposite an electrical conductor 111, 112, 113 in order to measure the intensity of the magnetic field induced by the circulation of a current in said electrical conductor 111, 112, 113.

The sensitive element 44 provides measurements of intensity of the magnetic field to the electronic card 15A, 20A on which it is mounted such that said electronic card 15A, 20A can convert it into a value proportional to current intensity or instead such that the electronic card 15A, 20A can observe the variations in intensity of the magnetic field which are proportional to the variations in intensity of the current circulating in the electrical conductor 111, 112, 113. The measurement sensors 40 are for example Hall effect sensors, known per se.

Each assembly 1A, 1B includes an electrical conductor 111, 112, 113 and a measurement sensor 40 and a magnetic core 50A, 50B surrounding a portion of the electrical conductor 111, 112, 113 at the level of which the sensitive element 44 of the measurement sensor 40 is placed.

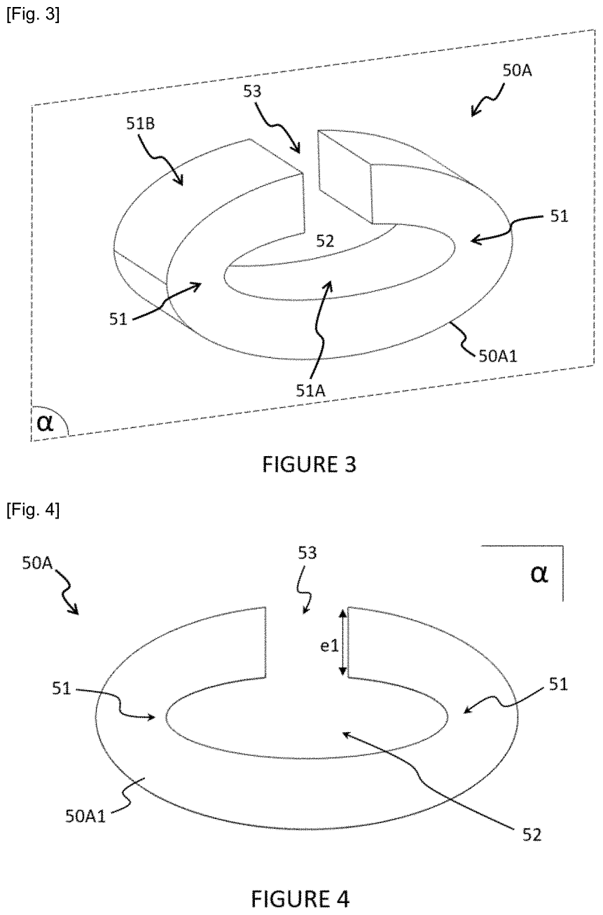

The magnetic core 50A, 50B includes at least one ferromagnetic part 50A1, 50B1 comprising at least one concave portion 51 extending along a longitudinal plane a and delimiting an inner space 52 and at least one air gap 53. The magnetic core 50A, 50B has a longitudinal section of elliptical shape. The terms “elliptical section” are taken to mean in the present description that the longitudinal section of the magnetic core 50A, 50B has a section of shape at least in part elliptical at the level of its inner surface, also called inner edge, 51A, whatever the number of parts 50A1, 50B1 that it comprises. In the embodiment illustrated in FIGS. 3 to 5 and 8 to 11, the longitudinal section of the magnetic core 50A, 50B is elliptical not just at the level of its outer surface 51B but also its inner surface 51A. Preferably, the at least one ferromagnetic material is a ferroalloy, preferably an alloy of iron and silicon (ferrosilicon or iron silicide), preferably laminated in order to reduce the hysteresis cycle of the material, thus losses, and to improve the precision of the current measurement.

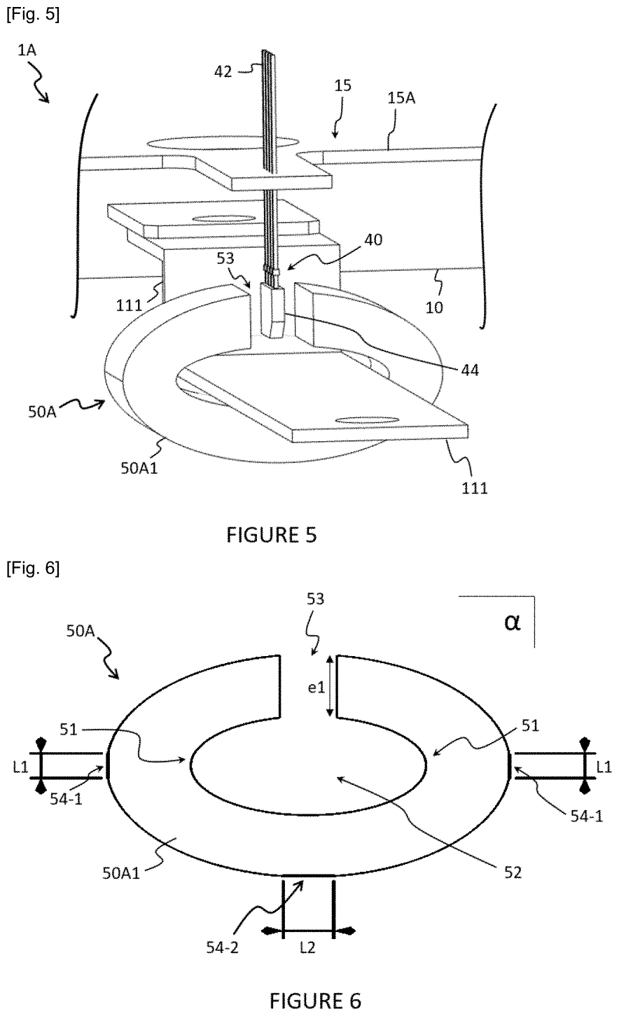

In a first embodiment illustrated in FIGS. 2 to 7 (assembly 1A), the magnetic core 50A is constituted of a single monobloc ferromagnetic part 50A1 having an elliptical section and delimiting a single air gap 53 making it possible to receive the sensitive element 44, as illustrated in particular in FIG. 5. The elliptical section of the part 50A1 defines an inner space 52 into which the strip of the electrical conductor 111, 112, 113 extends.

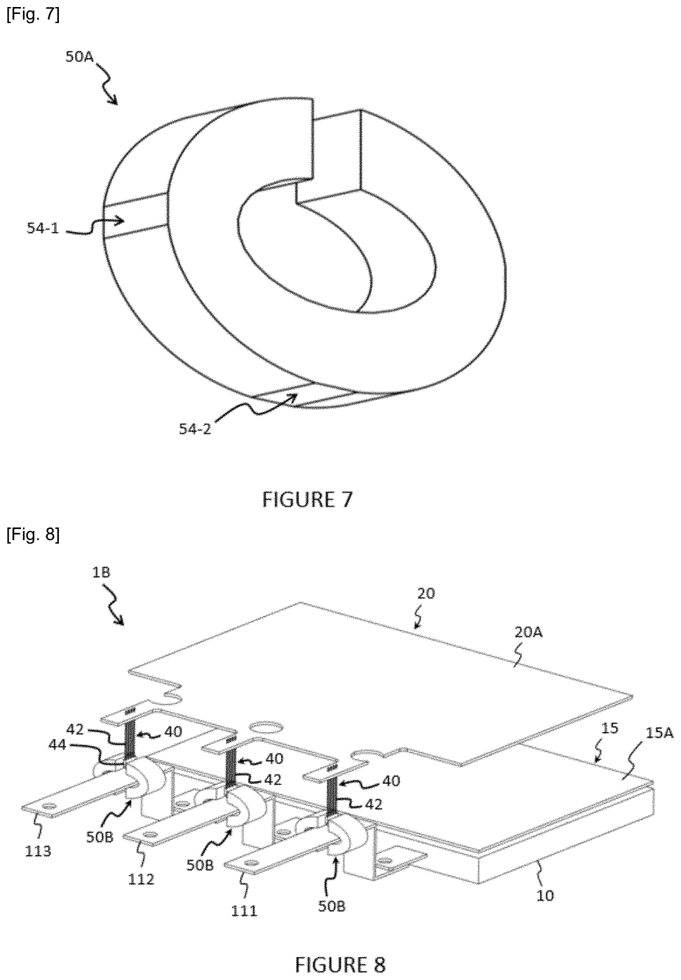

In an alternative of this first embodiment, illustrated in FIGS. 6 and 7, the ends of the part 50A are flattened. Put another way, the part 50A has, at the level of its ends, flat portions 54-1, 54-2 in order to enable easier positioning of the part 50A during overmoulding as will be described hereafter. Preferably, as illustrated in FIG. 6, the width L1 of the flat portions 54-1 situated on the large radius of the part 50A is less than 8 mm and the width L2 of the flat portion 54-2 situated on the small radius of the part 50A (opposite the air gap 53) is less than 10 mm.

In a second embodiment illustrated in FIGS. 8 to 11 (assembly 1B), the magnetic core 50B is constituted of two monobloc ferromagnetic parts 50B1, identical, of which the longitudinal section has, when they are opposite to each other, an elliptical shape such that, when they are positioned around the strip of the electrical conductor 111, 112, 113, the longitudinal section of the assembly formed by the two parts 50B1 is elliptical and delimits two air gaps 53, the sensitive element 44 of the corresponding measurement sensor 40 extending into one of the two air gaps 53. The two parts 50B1 are symmetrical with respect to each other with respect to a median plane perpendicular to the longitudinal plane.

In an alternative (not represented) of this second embodiment, each part 50B1 could include at its end a flat portion in order to facilitate their overmoulding.

In the first as in the second embodiment, the effective length of the part(s) 50A1, 50B1 (when they are mounted around an electrical conductor 111, 112, 113) is preferably less than 50 mm. Similarly, the width of the part(s) 50A1, 50B1 is preferably less than 28 mm and the reluctance of the magnetic core 50A, 50B is preferably less than 80000 Sturgeon (Henry⁻¹). In the first as in the second embodiment, the width of the air gap(s) is advantageously comprised between 3 and 8 mm, preferably comprised between 3.5 and 5 mm. In the first as in the second embodiment, the thickness e1 of the elliptical sector, that is to say of the part(s) 50A1, 50B1, is advantageously comprised between 3 and 12 mm, preferably of the order of 5 mm.

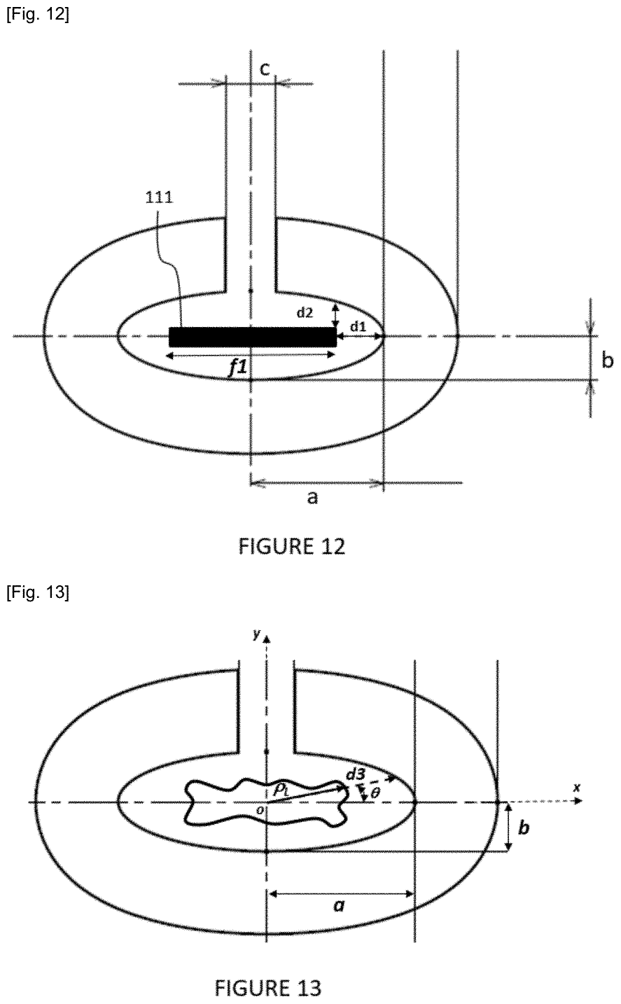

In the example of FIG. 12, the electrical conductor 111, 112, 113 has a parallelepiped section and is centred on the centre of the ellipse and in which the half major axis a and the half minor axis b of the ellipse are such that

$$a \geq \frac{f 1}{2} + d 1 , \qquad [ Math . 5 ]$$

where f1 is the thickness of the electrical conductor 111, 112, 113 along the direction of the major axis a, d1 is a first margin between the periphery of the conductor and the inner edge of the magnetic core 50A, 50B along the major axis a and b is such that the minimum distance between the periphery of the conductor and the inner edge of the magnetic core 50A, 50B, along a direction parallel to the minor axis b, is greater than or equal to d2, d2 being a second margin between the periphery of the electrical conductor 111, 112, 113 and the inner edge of the magnetic core 50A, 50B.

Preferably,

$$a = \frac{f 1}{2} + d 1 \qquad [ Math . 6 ]$$

and b is such that the minimum distance between the overall size and the inner edge of the magnetic core 50A, 50B along a direction parallel to the minor axis b is equal to d2.

With reference to FIG. 13, the inner edge of the magnetic core 50A, 50B has a longitudinal section of ellipse shape, said ellipse being the smallest ellipse confined to the overall size of the conductor 111, 112, 113 (in particular the portion of the conductor 111, 112, 113 comprised in the inner volume) with a minimum distance d3 between the overall size of the electrical conductor 111, 112, 113 and said inner edge. The inner edge corresponds to the part of the ellipse which defines the inner volume of the magnetic core 50A, 50B. The overall size corresponds to the external dimensions of the electrical conductor 111, 112, 113 in the inner volume defined by the magnetic core 50A, 50B. The minimum distance d3 may be positive or zero.

The ellipse is defined by the equation:

$${( \frac{x}{a} )}^{2} + {( \frac{y}{b} )}^{2} = 1 , \qquad [ Math . 7 ]$$

where a is the half major axis and b the half minor axis, x and y are the coordinates along the reference point defined by the half major axis a and the half minor axis b of the ellipse of centre O.

Preferably, one chooses:

$$\frac{a \times b}{\sqrt[2]{{b}^{2} {cos}^{2} ( θ ) + {a}^{2} {sin}^{2} ( θ )}} - {ρ}_{L} ( θ ) \geq d 3 \qquad [ Math . 8 ]$$

where

θ∈[0,2π] [Math. 9]

where

### [Math. 10]

ρL(θ) is the greatest distance of the longitudinal section of the electrical conductor 111, 112, 113 from the centre of the ellipse and

### [Math. 11]

θ is the angle between the major axis of the ellipse and a straight line passing through the centre of the ellipse. Further preferably, one has: 1 mm<d1<5 mm and/or 0.5 mm<d2<5 mm and/or 0.5 mm<d3<5 mm. The distance d3 and the distances d1 and d2 making it possible to ensure an electrical isolation between the electrical conductor and the magnetic core 50A, 50B. For example, a=9 mm and b=3 mm and c=3.4 mm (c being the width of the air gap 53). The width of the magnetic cores (width of the longitudinal section) may be comprised between 4 and 10 mm.

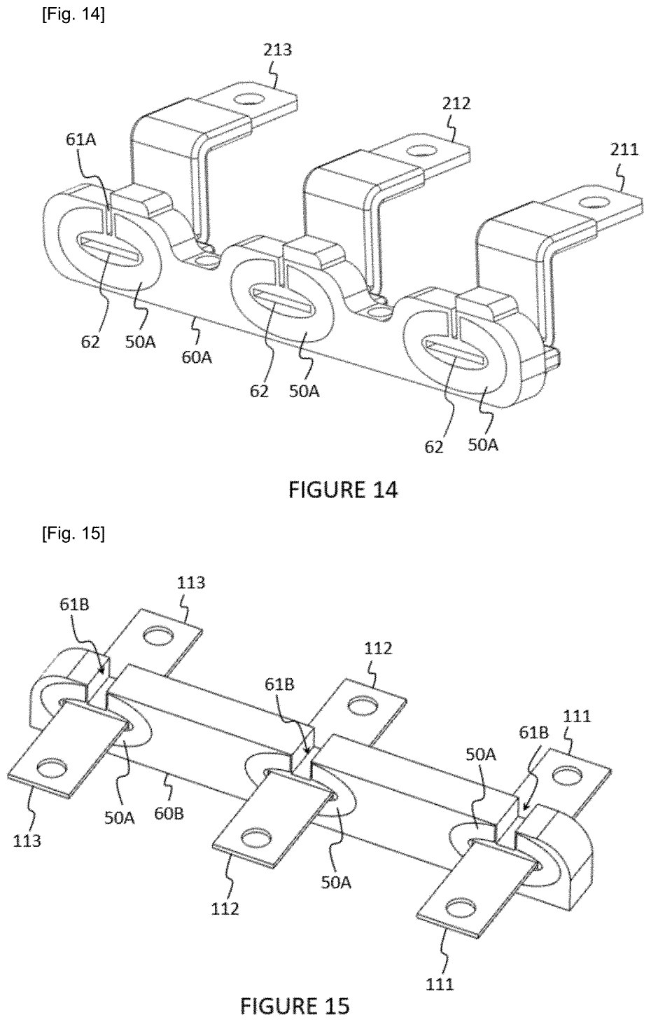

With reference to FIGS. 14 and 15, advantageously, the assembly 1A, 1B may include an overmoulding 60A, 60B surrounding at least partially the magnetic cores 50A, 50B in order to maintain them around the strips of the electrical conductors 111, 112, 113 during their mounting in the inverter.

Thus, in the example illustrated in FIG. 14, the overmoulding 60A entirely envelops the magnetic cores 50A. A port 61A, of which the width is substantially of the order of half of the width of the air gap 53, is formed in the overmoulding 60A at the level of each air gap 53 to insert therein the sensitive element 44 of the measurement sensor 40. Moreover, the overmoulding 60A occupies the inner space 52 of the magnetic core 50A, with the exception of a slot 62 into which the electrical conductors 111, 112, 113 are inserted. The assembly 1A further includes second electrical conductors 211, 212, 213. After insertion into the slot 62, the conductors 111, 112, 113 are then connected to second respective electrical conductors 211, 212, 213.

In the example illustrated in FIG. 15, the overmoulding 60B entirely envelops the magnetic cores 50A as well as the portions of electrical conductors 111, 112, 113 situated in the inner space 52 of said magnetic cores 50A. A port 61B, of which the width is substantially of the order of the width of the air gap 53, is formed in the overmoulding 60B at the level of each air gap 53 to insert therein the sensitive element 44 of the measurement sensor 40. In this example, the electrical conductors 111, 112, 113 may not be overmoulded with the overmoulding 60B. Thus, the conductors 111, 112, 113 may be inserted into slots 62 similar to those of FIG. 14. in this example of FIG. 15, the electrical conductors 111, 112, 113 are straight strips (i.e. not folded).

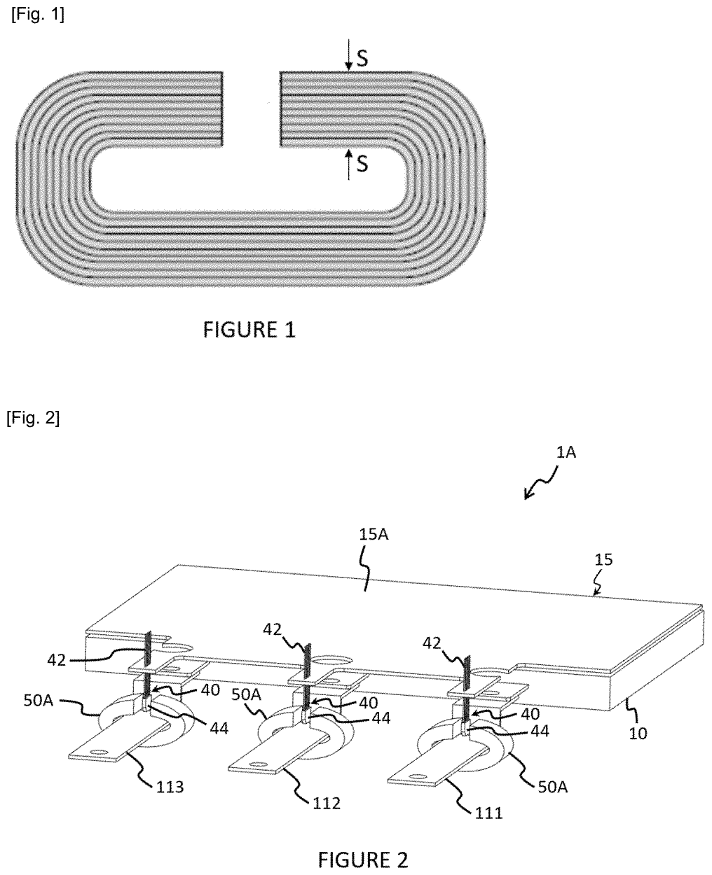

At equal great length and great width, the invention advantageously makes it possible to improve the linearity range of the current sensor integrating the magnetic core. Thus, by comparing the magnetic core with a magnetic core of the prior art such as illustrated in FIG. 1, at identical material and section an increase of the order of 10% of the reluctance is obtained and a corresponding increase in the linearization range. For example, at equal great length (25 mm) and great width (10 mm), an effective length of 48.18 mm is obtained with the design according to the invention compared to 52.43 mm with a rectangular design of the prior art, i.e. a ratio of

$$\frac{52.43}{48.18} = 1.09 ( 9 \% increase ) \qquad [ Math . 12 ]$$

which also is equal to the ratio of the reluctances.

It may be noted that the magnetic core according to the invention could also be mounted around electrical conductors of positive and negative potential connected to a battery in order to enable the measurement of the intensity of the magnetic field induced by the circulation of a current in said electrical conductors of positive and negative potential. It may further be noted that the dimensions and the shapes of the electrical conductors 111, 112, 113, and the measurement sensors 40 illustrated in the figures cannot in any way limit the scope of the present invention.

What is claimed is:

1. A magnetic core for a current measurement sensor, said magnetic core comprising at least one ferromagnetic part, comprising at least one concave portion, extending along a longitudinal plane (α) and delimiting at least in part an air gap, said air gap being capable of receiving a sensitive element of a measurement sensor, and the concave portion delimiting an inner space, capable of receiving an electrical conductor, wherein said magnetic core has a longitudinal section of elliptical shape.

2. The magnetic core according to claim 1, comprising a single ferromagnetic part delimiting a single air gap or comprising two opposite ferromagnetic parts delimiting two air gaps.

3. An electrical connection assembly, comprising at least one electrical conductor and at least one magnetic core, said magnetic core comprising at least one ferromagnetic part, comprising at least one concave portion, extending along a longitudinal plane (α) and delimiting at least in part an air gap, said air gap being capable of receiving a sensitive element of a measurement sensor, and the concave portion delimiting an inner space, capable of receiving an electrical conductor, wherein said magnetic core has a longitudinal section of elliptical shape, in which the electrical conductor extends through the magnetic core such that the magnetic core channels into its at least one air gap magnetic fields generated by a current circulating in the electrical conductor.

4. The electrical connection assembly according to claim 3, comprising a plurality of electrical conductors and a plurality of magnetic cores, each electrical conductor extending into the inner space of a respective magnetic core.

5. The electrical connection assembly according to claim 4, comprising an overmoulding holding together the magnetic cores.

6. The electrical connection assembly according to claim 3, in which the inner edge of the magnetic core has a longitudinal section of ellipse shape, said ellipse being the smallest ellipse confined to the overall size of the electrical conductor with a minimum distance d3 between the overall size of the electrical conductor and said inner edge.

7. The electrical connection assembly according to claim 3, in which the electrical conductor has a parallelepiped section and is centred on the centre of the ellipse and in which the half major axis a and the half minor axis b of the ellipse are such that
$$a \geq \frac{f 1}{2} + d 1$$
where f1 is the thickness of the electrical conductor along the direction of the major axis a and d1 is a first margin between the periphery of the electrical conductor and the inner edge of the magnetic core along the major axis a and b is such that the minimum distance between the periphery of the electrical conductor and the inner edge of the magnetic core, along a direction parallel to the minor axis b, is greater than or equal to d2, d2 being a second margin between the periphery of the electrical conductor and the inner edge of the magnetic core.

8. The electrical connection assembly according to claim 7, in which
$$a = \frac{f 1}{2} + d 1$$
and b is such that the minimum distance between the overall size and the inner edge of the magnetic core along a direction parallel to the minor axis B is equal to d2.

9. The electrical connection assembly according to claim 7, in which 1 mm<d1<5 mm and/or 0.5 mm<d2<5 mm and/or, when claim 7 depends on claim 6, 0.5 mm<d3<5 mm.

10. A sensor assembly comprising:
an electrical connection assembly, comprising at least one electrical conductor and at least one magnetic core, said magnetic core comprising at least one ferromagnetic part, comprising at least one concave portion, extending along a longitudinal plane (α) and delimiting at least in part an air gap, said air gap being capable of receiving a sensitive element of a measurement sensor, and the concave portion delimiting an inner space, capable of receiving an electrical conductor, wherein said magnetic core has a longitudinal section of elliptical shape, in which the electrical conductor extends through the magnetic core such that the magnetic core channels into its at least one air gap magnetic fields generated by a current circulating in the electrical conductor; and
a measurement sensor comprising a sensitive element extending into the at least one air gap of the at least one magnetic core, said sensitive element being configured in such a way as to measure the intensity of the magnetic field induced by a current circulating in the at least one corresponding electrical conductor.

11. The electrical connection assembly according to claim 4, in which the inner edge of the magnetic core has a longitudinal section of ellipse shape, said ellipse being the smallest ellipse confined to the overall size of the electrical conductor with a minimum distance d3 between the overall size of the electrical conductor and said inner edge.

12. The electrical connection assembly according to claim 5, in which the inner edge of the magnetic core has a longitudinal section of ellipse shape, said ellipse being the smallest ellipse confined to the overall size of the electrical conductor with a minimum distance d3 between the overall size of the electrical conductor and said inner edge.

13. The electrical connection assembly according to claim 4, in which the electrical conductor has a parallelepiped section and is centred on the centre of the ellipse and in which the half major axis a and the half minor axis b of the ellipse are such that
$$a \geq \frac{f 1}{2} + d 1$$
where f1 is the thickness of the electrical conductor along the direction of the major axis a and d1 is a first margin between the periphery of the electrical conductor and the inner edge of the magnetic core along the major axis a and b is such that the minimum distance between the periphery of the electrical conductor and the inner edge of the magnetic core, along a direction parallel to the minor axis b, is greater than or equal to d2, d2 being a second margin between the periphery of the electrical conductor and the inner edge of the magnetic core.

14. The electrical connection assembly according to claim 5, in which the electrical conductor has a parallelepiped section and is centred on the centre of the ellipse and in which the half major axis a and the half minor axis b of the ellipse are such that
$$a \geq \frac{f 1}{2} + d 1$$
where f1 is the thickness of the electrical conductor along the direction of the major axis a and d1 is a first margin between the periphery of the electrical conductor and the inner edge of the magnetic core along the major axis a and b is such that the minimum distance between the periphery of the electrical conductor and the inner edge of the magnetic core, along a direction parallel to the minor axis b, is greater than or equal to d2, d2 being a second margin between the periphery of the electrical conductor and the inner edge of the magnetic core.

15. The electrical connection assembly according to claim 6, in which the electrical conductor has a parallelepiped section and is centred on the centre of the ellipse and in which the half major axis a and the half minor axis b of the ellipse are such that
$$a \geq \frac{f 1}{2} + d 1$$
where f1 is the thickness of the electrical conductor along the direction of the major axis a and d1 is a first margin between the periphery of the electrical conductor and the inner edge of the magnetic core along the major axis a and b is such that the minimum distance between the periphery of the electrical conductor and the inner edge of the magnetic core, along a direction parallel to the minor axis b, is greater than or equal to d2, d2 being a second margin between the periphery of the electrical conductor and the inner edge of the magnetic core.

16. The electrical connection assembly according to claim 8, in which 1 mm<d1<5 mm and/or 0.5 mm<d2<5 mm and/or, when claim 7 depends on claim 6, 0.5 mm<d3<5 mm.

17. The electrical connection assembly according to claim 3, wherein the magnetic core comprises a single ferromagnetic part delimiting a single air gap or comprises two opposite ferromagnetic parts delimiting two air gaps.

18. The sensor assembly according to claim 10, wherein the electrical connection assembly comprises a plurality of electrical conductors and a plurality of magnetic cores, each electrical conductor extending into the inner space of a respective magnetic core.

19. The sensor assembly according to claim 18, wherein the electrical connection assembly comprises an overmoulding holding together the magnetic cores.

20. The sensor assembly according to claim 10, in which the inner edge of the magnetic core has a longitudinal section of ellipse shape, said ellipse being the smallest ellipse confined to the overall size of the electrical conductor with a minimum distance d3 between the overall size of the electrical conductor and said inner edge.
